(19) United States
(12) Patent Application Publication
(10) Pub. No.: US 2003/0141104 A1
(43) Pub. Date: Jul. 31, 2003

(54) Electronic printed-circuit board for electronic devices, especially communications terminals

(76) Inventors: Heinrich Bruckmann, Bocholt (DE); Georg Busch, Ahaus (DE); Ludger Hinken, Bocholt (DE)

Correspondence Address: BELL, BOYD & LLOYD, LLC, P. O. BOX 1135, CHICAGO, IL, 60690-1135, US

(21) Appl. No.: 10/204,723

(22) PCT Filed: Feb. 23, 2001
(86) PCT No.: PCT/DE01/00711

(30) Foreign Application Priority Data
Feb. 23, 2000 (DE) 100 08 340.4

(51) Int. Cl. H05K 1/14; H05K 1/03

(52) U.S. Cl. 174/256; 361/803; 174/258; 361/771

(57) ABSTRACT

The aim of the invention is to improve the modular assembly technique used for assembling electronic printed-circuit boards (FBG1, FBG2) for electronic devices in order to incorporate the printed-circuit boards in electronic devices with electronic printed-circuit boards of the type mentioned above more flexibly in terms of the printed-circuit board material, in accordance with the respective field of application, size and weight requirements and manufacturing costs of the devices. To this end, the electronic devices are modularly assembled in terms of the printed-circuit board construction, with at least two printed-circuit boards (FBG1, FBG2) consisting of different materials with different temperature and length-related expansion coefficients. The individual printed-circuit boards are fixed with electroconductive fixing means (LB) in such a way that when they are in their fixed state, inner electrical, mechanically stable connections are provided between the two printed-circuit boards, concealed by the printed-circuit boards, in an intermediate assembly gap (MZR) formed by the printed-circuit boards. The different temperature and length-related expansion coefficients associated with the materials ensure that there are no material stresses that could destroy the connections.

The invention relates to an electronic printed circuit board assembly according to the preamble of patent claim 1.

Electronic devices, for example devices from the consumer goods industries such as entertainment electronics, communications technology etc., for example radio sets and television sets, hi-fi equipment, telephones for wire-bound and wire-free communication, portable video phones, Web telephones and LAN telephones, LAN adapters, mainly have a single electronic printed circuit board assembly for the functions which are to be implemented in the respective device and the individual equipment parts which are necessary for that purpose. In the devices which have more than two printed circuit board assemblies, modular design technology is applied for the design of the printed circuit board assemblies. Here, circuits and components are combined according to their respective function on separate printed circuit board assemblies in the electronic device before the printed circuit board assemblies which have been produced in this way, and are also referred to as modules, are connected to form a unit which determines the operational capability of the electronic device. The modular design technology is preferably applied if the circuits and components which are to be implemented in the electronic device make different requirements of the printed circuit boards which are provided for them.

Thus, for example in an electronic high frequency device having high frequency circuits and high frequency components as well as low frequency circuits and low frequency components it is possible for the low frequency circuits and low frequency components to be integrated, for means of economy, on one printed circuit board which, in contrast to the printed circuit board for the high frequency circuits and high frequency components, has to satisfy lower requirements in terms of the printed circuit board quality owing to the less critical physical properties of the low frequency circuit and low frequency components.

The printed circuit board with the high frequency circuits and high frequency components will therefore preferably be at least one, for example, multilayer FR4 printed circuit board, while the printed circuit board with the low frequency circuits and low frequency components will preferably be at most a, for example, multilayer FR3 printed circuit board.

In electronic high frequency devices such as the “GIGASET” DECT devices from Siemens, a, for example, four-layer FR4 printed circuit board was absolutely necessary in the past owing to the high frequency circuits and components. The printed circuit board technology is determined here essentially by the high frequency circuits and the high frequency components. In most cases, a cheap printed circuit board technology would be sufficient for the low frequency circuits and the low frequency components.

As a further example of modular design technology, in an electronic device which has exclusively low frequency circuits and components but in which different integration densities of the low frequency circuits and low frequency components are to be implemented, the printed circuit board with the lower integration density of low frequency circuits and low frequency components is capable of satisfying lower quality requirements than the printed circuit board with the higher integration density of low frequency circuits and low frequency components. The printed circuit board with the lower integration density will therefore preferably again be at most the, for example, multilayer FR3 printed circuit board, while the printed circuit board with the higher integration density will preferably again be at least the, for example, multilayer FR4 printed circuit board.

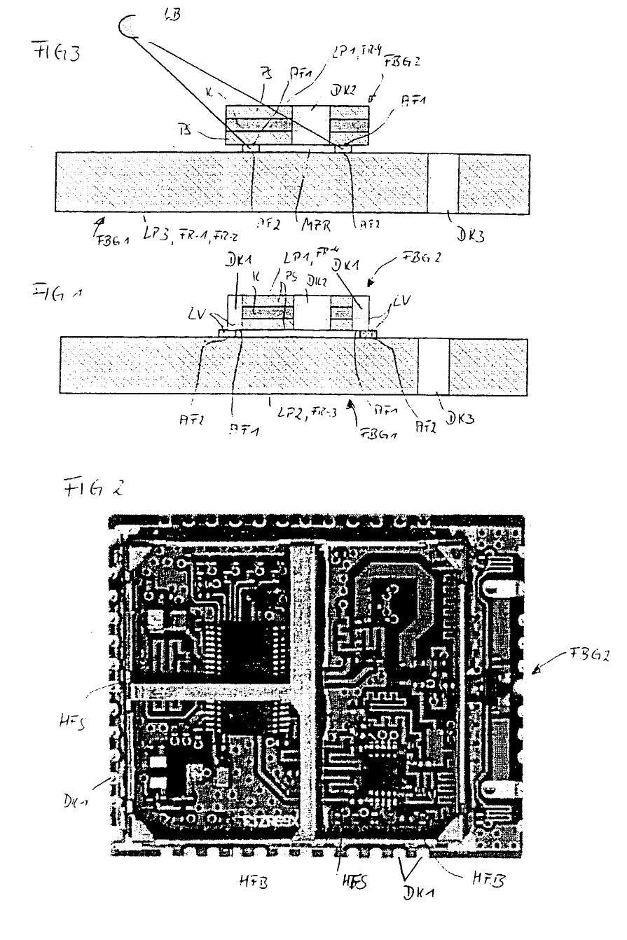

The prior art in terms of the modular design of printed circuit board assemblies will be explained with reference to FIGS. 1 and 2, of which:

FIG. 1 is a basic representation of the modular design technology for printed circuit board assemblies of electronic devices,

FIG. 2 is a plan view of the component side of a high frequency printed circuit board assembly of an electronic high frequency device.

FIG. 1 shows how, in the modular design technology for printed circuit board assemblies a first printed circuit board assembly FBG1 serves as a carrier for a second printed circuit board assembly FBG2 which is embodied as a module, and how the second printed circuit board assembly FBG2 is secured here at the edges to the first printed circuit board assembly FBG1 by means of solder connections LV. In order to attach the second printed circuit board assembly FBG2 to the first printed circuit board assembly FBG1 via the solder connections LV, the second printed circuit board assembly FBG2 has, at the edges, first vias DK1 which are slightly cut in order to ensure simple and reliable mounting of the second printed circuit board assembly FBG2 on the first printed circuit board assembly FBG1. So that circuits and components which make special requirements of the printed circuit board material, for example an epoxy glass fabric, of the printed circuit board assembly can be accomodated on the second printed circuit board assembly FBG2 if, for example, high frequency circuits and high frequency components are to be integrated on the second printed circuit board assembly FBG2 or if a high integration density of circuits and components is to be implemented on the second printed circuit board assembly FBG2, said second printed circuit board assembly FBG2 is composed of a high quality printed circuit board material, for example of a four-layer first printed circuit board LP1 which is made of FR4 material and has a core K and a prepreg layer PS arranged respectively below and above the core K. The layered structure formed of the core K and the two prepreg layers PS results in the four layers of the printed circuit board LP1.

In order to gain access to the individual layers of the printed circuit board LP1 in the printed circuit board layout, the printed circuit board LP1 also has two vias DK2.

In contrast to the second printed circuit board assembly FBG2, the first printed circuit board assembly FBG1 is composed of a printed circuit board material which is of not such high quality, for example made of epoxy glass fabric with larger temperature-related and length-related coefficients of expansion than the epoxy glass fabric of the FR4 material because circuits and components which do not make any special requirements of the printed circuit board material of the printed circuit board assembly are arranged there, for example if low frequency circuits and low frequency components are to be integrated on the first printed circuit board assembly FBG1 or if a low integration density of circuits and components is to be implemented on the first printed circuit board assembly FBG1. In this case, a two-layer second printed circuit board LP2 made of FR3 material has been selected as the printed circuit board material, which material is, on the one hand, not of such high quality in comparison with the FR4 printed circuit board material of the second printed circuit board assembly FBG2 because of the larger coefficients of expansion, but, on the other hand, hardly differs from the FR4 printed circuit board material in terms of the temperature-related and length-related coefficients of expansion. Owing to this slight difference in the coefficients of expansion it is possible to secure the second printed circuit board assembly FBG2 at the edges to the first printed circuit board assembly FBG1 without material stresses which destroy the connections between the printed circuit board assemblies occurring with time or when there is mechanical stressing owing to the different temperature-related and length-related coefficients of expansion of the printed circuit board materials used.

If, however, the coefficients of expansion of the printed circuit board materials used differ significantly from one another, for example FR4 material in the second printed circuit board assembly FBG2 in contrast with FR1 material or FR2 material in the first printed circuit board assembly FBG1, material stresses occur during the attachment of the edges of the second printed circuit board assembly FBG2 to the first printed circuit board assembly FBG1, which stresses can destroy these attachments with time or when there is mechanical stressing of the printed circuit board assembly arrangement or printed circuit board assembly unit.

A further criterion which has negative effects for the destructability of the edge attachment is that the partially cut via DK1 results in first connecting areas AF1 of the second printed circuit board assembly FBG2 not being located directly above or below second connecting areas AF2 of the first printed circuit board assembly FBG1.

In order to gain access to the individual layers of the printed circuit board LP2 in the printed circuit board layout, the printed circuit board LP2 also has third vias DK3.

FIG. 2 shows a plan view of a high frequency printed circuit board assembly with high frequency circuits HFS and high frequency components HFB of an electronic high frequency device which has the partially cut vias DK1 according to FIG. 1 at the edges.

The object on which the invention is based is to improve the modular design technology applied in the design of electronic printed circuit board assemblies for electronic devices in such a way that, in electronic devices with electronic printed circuit board assemblies—of the type mentioned at the beginning—it is possible, depending on the field of application and requirements in terms of size, weight and manufacturing costs of the devices, to use printed circuit board assemblies in a flexible manner in respect of the material of the printed circuit board assembly without the disadvantages known from the prior art occurring.

This object is achieved on the basis of the electronic printed circuit board assembly defined in the preamble of patent claim 1 by virtue of the features specified in the defining part of patent claim 1.

The idea on which the invention is based is to construct electronic devices in a modular fashion in terms of the design concept for printed circuit board assemblies, using at least two printed circuit board assemblies which are manufactured from different materials with different temperature-related and length-related coefficients of expansion, and to secure the individual printed circuit board assemblies by means of electrically conductive securing means in such a way that in the secured state of the printed circuit board assemblies, on the one hand intimate electrical and on the other hand stable mechanical connections, which are concealed by the printed circuit board assemblies in a mounting intermediate space formed by the printed circuit board assemblies, are produced between the two printed circuit board assemblies, and there is no occurrence of material stresses which destroy the connections owing to the different temperature-related and length-related coefficients of expansion due to the materials.

As a result, the following advantages are obtained:

considerable reduction in the printed circuit board costs

use of different printed circuit board materials

flexibility in product development

reduction in development expenditure

opening up of new business areas

Due to the modular design technology, decoupling of a high frequency printed circuit board assembly and low frequency printed circuit board assembly is possible in electronic high frequency devices, for example the DECT devices, according to patent claim 2 and/or patent claim 5. This decoupling therefore enables different printed circuit board technologies to be used. A high quality printed circuit board technology is used in the high frequency printed circuit board assembly, while a cheap printed circuit board technology is used in the low frequency printed circuit board assembly.

In this way, highly sensitive DECT circuits can be implemented on printed circuit boards made of hard paper, which is preferably manufactured on a phenol resin basis according to patent claim 6 (for example conductive silver paste technology with fine structures) while fulfilling all the environmental parameters, for example electromagnetic compatibility EMC.

In order to obtain a stable mechanical connections between the two printed circuit board assemblies in the development according to patent claim 5, it is necessary to reduce the size and the weight of the second printed circuit board assembly or high frequency printed circuit board assembly embodied as a high frequency module. This then also makes it possible to mount the high frequency module reliably in terms of processes and equip it with SMDs automatically.

The development according to patent claim 2 implements a shielding concept for high frequency circuits and high frequency components in electronic high frequency devices, in which the effect on the levelness between the first printed circuit board assembly and second printed circuit board assembly is small for mounting of the second printed circuit board assembly on the first printed circuit board assembly in a way which is reliable for processes. Furthermore, it is possible to integrate the high frequency antenna cost-effectively on the first printed circuit board assembly with the cheaper printed circuit board technology.

Solder balls which are embodied as what are referred to as lot balls or ball grid arrays (BGA) and which permit a cost-effective connection of two printed circuit boards with different materials in Reflow ovens are used as the securing means for connecting the printed circuit board assemblies according to the development as claimed in patent claim 10. Reliability in terms of processes is achieved by applying the solder balls using the BGA technology on the first and/or second printed circuit board assembly.

Further advantageous developments of the invention are given in the further subclaims.

An exemplary embodiments of the invention is shown based on the prior art according to FIGS. 1 and 2 in FIGS. 3 to 6, in which:

FIG. 3 shows, based on FIG. 2, a basic view of a modified modular design technology for printed circuit board assemblies of electronic devices,

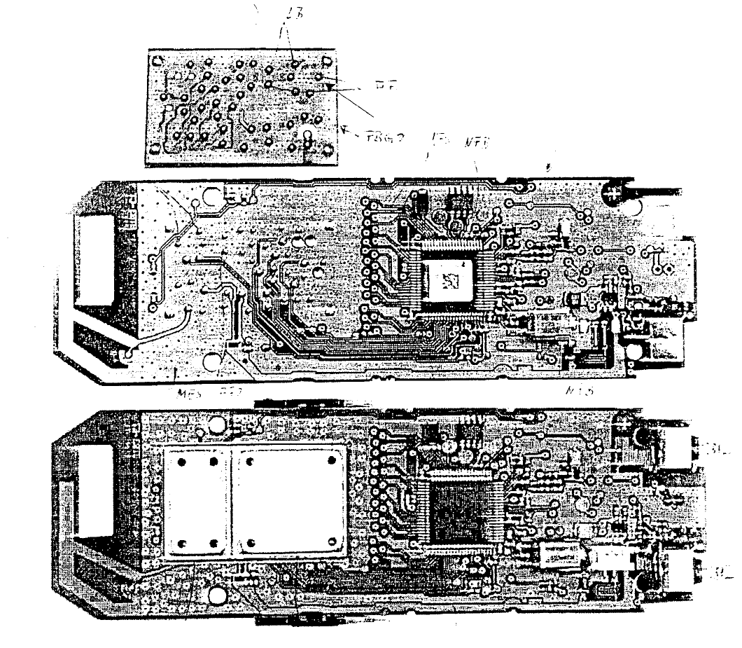

FIG. 4 shows a plan view of the underside of a high frequency printed circuit board assembly, embodied according to FIG. 3, of an electronic high frequency device,

FIG. 5 shows a plan view of the component side of a low frequency printed circuit board assembly, embodied according to FIG. 3, of the electronic high frequency device,

FIG. 6 shows a plan view of the high frequency printed circuit board assembly and low frequency printed circuit board assembly, connected to one another, of the electronic high frequency device.

FIG. 3 shows, based on FIG. 1, a modified modular design technology for printed circuit board assemblies of electronic devices. As in FIG. 1, the first printed circuit board assembly FBG1 serves as a carrier for the second printed circuit board assembly FBG2 which is embodied as a module. So that circuits and components which make special requirements of the printed circuit board material, for example an epoxy glass fabric or a film with comparable properties, of the printed circuit board assembly can be accommodated on the second printed circuit board assembly FBG2—if, for example, high frequency circuits and high frequency components are to be integrated on the second printed circuit board assembly FBG2 or if a high integration density of circuits and components is to be implemented on the second printed circuit board assembly FBG2, said second printed circuit board assembly FBG2 is composed, as in FIG. 1, of a high quality printed circuit board material, for example of the four-layer first printed circuit board LP1 which is made of FR4 material and has the core K and the prepreg layer PS arranged respectively below and above the core K. The layered structure formed of the core K and the two prepreg layers PS results in the four layers of the printed circuit board LP1.

In order to gain access to the individual layers of the printed circuit board LP1 in the printed circuit board layout, the printed circuit board LP1 has in turn the second vias DK2.

In contrast to the second printed circuit board assembly FBG2, the first printed circuit board assembly FBG1 is, in turn, composed of a printed circuit board material which is not of such high quality and which is, however, of even lower quality than the first printed circuit board assembly FBG1 in FIG. 1, as the temperature-related and length-related coefficient of expansion are even larger. As in FIG. 1, circuits and components which make special requirements of the printed circuit board material of the printed circuit board assembly are arranged on the first printed circuit board assembly FBG1, for example if low frequency circuits and low frequency components are to be integrated on the first printed circuit board assembly FBG1 or if a low integration density of circuits and components is to be implemented on the first printed circuit board assembly FBG1. In this case, a two-layer third printed circuit board LP3 which is made of FR1 or FR2 material, for example phenol resin hard paper or film with comparable properties and which differs significantly from the FR4 printed circuit board material in terms of the temperature-related and length-related coefficients of expansion has been selected as the printed circuit board material. Because of this significant difference in the coefficients of expansion, it is, as in FIG. 1, no longer possible to secure the second printed circuit board assembly FBG2 at the edges to the first printed circuit board assembly FBG1 without material stresses which destroy the connections between the printed circuit board assemblies occurring with time or when there is mechanical stressing owing to the different temperature-related and length-related coefficients of expansion of the printed circuit board materials used.

In order to gain access to the individual layers of the printed circuit board LP2 in the printed circuit board layout, the printed circuit board LP2 has in turn the third vias DK3.

In contrast to the means of securing the second printed circuit board assembly FBG2 on the first printed circuit board assembly FBG1 in FIG. 1, the second printed circuit board assembly FBG2 is now secured on the first printed circuit board assembly FBG1 by means of the ball grid array technology (BGA technology) in the form of solder balls.

The solder balls LB are mounted and arranged on the printed circuit board assemblies FBG1, FBG2 on the connecting areas AF1, AF2 in such a way that in the secured state of the printed circuit board assemblies FBG1, FBG2, on the one hand intimate electrical and on the other hand stable mechanical connections, which are concealed by the printed circuit board assemblies FBG1, FBG2 in a mounting intermediate space MZR, embodied for example as a gap, formed by the printed circuit board assemblies FBG1, FBG2 are produced between the two printed circuit board assemblies FBG1, FBG2, and there is no occurrence of material stresses which destroy the connections owing to the different temperature-related and length-related coefficients of expansion due to the materials.

As an alternative to the solder balls LB as securing means, it is also possible to use an aniosotopic bonding agent which is also electrically conductive. FIG. 4 shows the plan view of the underside of a high frequency printed circuit board assembly FBG2 which is embodied according to FIG. 3 and has high frequency circuits HFS of an electronic high frequency device on which the solder balls LB are mounted and arranged on the first connecting areas AF1 in such a way that in the secured state of the high frequency printed circuit board assemblies FBG2 with a low frequency printed circuit board assembly FBG1 with low frequency circuits NFS and low frequency components NFB of the electronic device according to FIG. 5, on which low frequency printed circuit board assembly FBG1 the solder balls LB are mounted and arranged on the second connecting areas AF2, on the one hand intimate electrical and on the other hand stable mechanical connections, which are concealed by the high frequency/low frequency printed circuit board assemblies FBG1, FBG2 in the mounting intermediate space MZR, formed by high frequency/low frequency printed circuit board assemblies FBG1, FBG2, for example formed as a gap, are produced between the two high frequency/low frequency printed circuit board assemblies FBG1, FBG2, and there is no occurrence of material stresses which destroy the connections owing to the different temperature-related and length-related coefficients of expansion due to the materials.

The connecting areas AF1, AF2 on the high frequency/low frequency printed circuit board assemblies FBG1, FBG2 are arranged according to FIGS. 4 and 5 in such a way that in the secured state of the high frequency/low frequency printed circuit board assemblies FBG1, FBG2 the connecting areas AF2 of the low frequency printed circuit board assembly FBG1 are located directly above or below the connecting areas AF1 of the high frequency printed circuit board assembly, FBG2, it being possible for the shape, geometry and size to be different. This reduces further the probability of the means of securing the printed circuit board assemblies being destroyed.

Moreover, the low frequency printed circuit board assembly FGB1 according to FIG. 5 has a large-area metalization layer MES which at least partially covers the low frequency printed circuit board assembly FBG1 and by means of which both internal electromagnetic interference influences, which are caused by the circuits NFS, HFS and components NFB, HFB and which interact with the circuits NFS, HFS and components NFB, HFB, and external electromagnetic interference influences are shielded. Such a metalization layer MES can alternatively or additionally be arranged on the high frequency printed circuit board assembly FBG2 according to FIG. 4, and is also at least partially covered by said high frequency printed circuit board assembly FBG2.

FIG. 6 shows a plan view of the high frequency printed circuit board assembly FBG2 according to FIG. 4 and low frequency printed circuit board assembly FBG1 according to FIG. 5 of the electronic high frequency device which are connected to one another. The high frequency printed circuit board assembly FBG2 which is mounted on the low frequency printed circuit board assembly FBG1 is connected, in the course of the shielding concept for shielding the internal and external electromagnetic interference influences, to a lightweight metal box LMK which tightly seals the high frequency circuits HFS and the high frequency components HFB on the high frequency printed circuit board assembly FBG2.

1. An electronic printed circuit board assembly for electronic devices, in particular communications terminals, having
(a) a first printed circuit board assembly (FBG1) which is embodied as a carrier,
(b) at least one second printed circuit board assembly (FBG2) which is secured on the first printed circuit board assembly (FBG1) using electrically conductive securing means (LB) in such a way that the latter is partially concealed,
(c) the two printed circuit board assemblies (FBG1, FBG2) are manufactured from different materials (FR1 . . . FR4) with different temperature-related and length-related coefficients of expansion,
(d) first circuits (NFS) and first components (NFB) being arranged on the first printed circuit board assembly (FBG1) or on the first and the second printed circuit board assemblies (FBG1, FBG2), and second circuits and (HFS) second components (HFB) being arranged on the second printed circuit board assembly (FBG2) or on the first and second printed circuit board assemblies (FBG1, FBG2), characterized in that
(e) on the printed circuit board assemblies (FBG1, FBG2) there are connecting areas (AF1, AF2) on which the securing means (LB) are mounted, and which are arranged on the printed circuit board assemblies (FBG1, FBG2), in such a way that, in the secured state of the printed circuit board assemblies (FBG1, FBG2), on the one hand intimate electrical and on the other hand stable mechanical connections, which are concealed by the printed circuit board assemblies (FBG1, FBG2) in a mounting intermediate space (MZR) formed by the printed circuit board assemblies (FBG1, FBG2) are produced between the two printed circuit board assemblies (FBG1, FBG2), and there is no occurrence of material stresses which destroy the connections owing to the different temperature-related and length-related coefficients of expansion due to the materials.

2. The electronic printed circuit board assembly as claimed in claim 1, characterized in that, with electronic high frequency devices, the first printed circuit board assembly (FBG1) and/or the second printed circuit board assembly (FBG2) each have at least one large-area metalization layer (MES) which at least partially covers the respective printed circuit board assemblies (FBG1, FBG2) and by means of which both internal electromagnetic interference influences, which are caused by the circuits (NFS, HFS) and components (NFB, HFB) and which interact with the circuits (NFS, HFS) and components (NFB, HFB), and external electromagnetic interference influences are shielded.

3. The electronic printed circuit board assembly as claimed in claim 1 or 2, characterized in that the connecting areas (AF1, AF2) are arranged on the printed circuit board assemblies (FBG1, FBG2) in such a way that, in the secured state of the printed circuit board assemblies (FBG1, FBG2), the connecting areas (AF2) of the first printed circuit board assembly (FBG1) are located directly above or below the connecting areas (AF1) of the second printed circuit board assembly (FBG2), it being possible for the shape, geometry and size to be different.

4. The electronic printed circuit board assembly as claimed in one of claims 1 to 3, characterized in that the second printed circuit board assembly (FBG2) is arranged, similarly to a component, on the component equipping side of the first printed circuit board assembly (FBG1).

5. The electronic printed circuit board assembly as claimed in one of claims 1 to 4, characterized in that, with electronic high frequency devices, the first circuits (NFS) and first components (NFB) are low frequency circuits and low frequency components and the second circuits (HFS) and second components (HFB) are high frequency circuits and high frequency components.

6. The electronic printed circuit board assembly as claimed in one of claims 1 to 5, characterized in that the material of the first printed circuit board assembly (FGB1) is an, in particular copper-coated phenol resin hard paper.

7. The electronic printed circuit board assembly as claimed in one of claims 1 to 5, characterized in that the material of the first printed circuit board assembly (FBG1) is a film.

8. The electronic printed circuit board assembly as claimed in one of claims 1 to 7, characterized in that the material of the second printed circuit board assembly (FBG2) is an epoxy glass fabric.

9. The electronic printed circuit board assembly as claimed in one of claims 1 to 7, characterized in that the material of the second printed circuit board assembly (FBG2) is a film.

10. The electronic printed circuit board assembly as claimed in one of claims 1 to 9, characterized in that the securing means (LB) are what are referred to as solder balls or solder balls (LB) embodied as ball grid arrays.

11. The electronic printed circuit board assembly as claimed in one of claims 1 to 9, characterized in that the securing means (LB) are anisotropic bonding agents.
